(19) United States
(12) Patent Application Publication
(10) Pub. No.: US 2014/0307384 A1
(43) Pub. Date: Oct. 16, 2014

(54) INTEGRATED COMPUTING MODULE WITH POWER AND LIQUID COOLING COMPONENTS

(71) Applicant: Green Revolution Cooling, Inc., Austin, TX (US)

(72) Inventor: Christiaan Scott Best, Austin, TX (US)

(73) Assignee: Green Revolution Cooling, Inc., Austin, TX (US)

(21) Appl. No.: 14/251,014

(22) Filed: Apr. 11, 2014

Related U.S. Application Data
(60) Provisional application No. 61/853,696, filed on Apr. 11, 2013.

(51) Int. Cl. H05K 7/20

(52) U.S. Cl. CPC H05K 7/20781
USPC 361/679.53

(57) ABSTRACT

A computing module includes one or more racks, one or more cooling components, and one or more power distribution components. The racks include one or more servers and one or more tanks that hold liquid coolant for the servers. The one or more cooling components move a liquid to remove heat from the servers. The one or more power distribution components supply power to the servers. The one or more racks, one or more cooling components, and one or more power distribution components are commonly coupled to one another to be movable as a unit.

### PRIORITY claim

This application claims the benefit of U.S. Provisional Application Ser. No. 61/853,696 entitled “Methods for Combining Power and Cooling into a Datacenter” filed Apr. 11, 2013, which is incorporated herein by reference in its entirety.

### BACKGROUND

1. Field

The present invention relates generally to providing resources for computing. More particularly, the present disclosure relates to systems and methods for integrating power and cooling components into a computing module.

2. Description of the Related Art

A data center typically includes a group of computing devices at a common physical location. Data centers are often housed in conventional building structures and use air conditioning systems to remove heat generated by electronic components (chips, hard drives, cards, etc.)

Many commercially-available servers used in data centers are designed for air cooling. Such servers usually comprise one or more printed circuit boards having a plurality of electrically coupled devices mounted thereto. These printed circuit boards are commonly housed in an enclosure having vents that allow external air to flow into the enclosure, as well as out of the enclosure after being routed through the enclosure for cooling purposes. In many instances, one or more fans are located within the enclosure to facilitate this airflow.

Data centers housing such servers and racks of servers typically distribute air among the servers using a centralized fan (or blower). As more fully described below, air within the data center usually passes through a heat exchanger for cooling the air (e.g., an evaporator of a vapor-compression cycle refrigeration cooling system (or “vapor-cycle” refrigeration), or a chilled water coil) before entering a server. In some data centers, the heat exchanger has been mounted to the rack to provide “rack-level” cooling of air before the air enters a server. In other data centers, the air is cooled before entering the data center.

In general, electronic components of higher performing servers dissipate correspondingly more power. However, power dissipation for each of the various hardware components (e.g., chips, hard drives, cards) within a server can be constrained by the power being dissipated by adjacent heating generating components, the airflow speed and airflow path through the server and the packaging of each respective component, as well as a maximum allowable operating temperature of the respective component and a temperature of the cooling air entering the server as from a data center housing the server. The temperature of an air stream entering the server from the data center, in turn, can be influenced by the power dissipation and proximity of adjacent servers, the airflow speed and the airflow path through a region surrounding the server, as well as the temperature of the air entering the data center (or, conversely, the rate at which heat is being extracted from the air within the data center).

It requires a substantial amount of space to house data centers in conventional buildings. In addition, servers deployed in buildings may not portable and may be expensive, as energy costs and power dissipation continue to increase. Air cooling of a data center is also space intensive, because the efficiency of cooling is affected by the proximity of electronic components.

Power distribution components, such as floor power distribution units and rack power distribution units, for a data center are often acquired separately from different vendors at different times, and put in the data center without comprehensive planning and design. As a result, power distribution components in many data centers are not properly sized or designed.

In addition, cooling capacity and power distribution capacity for computing resources are often not sized together. A common result is that infrastructure for computing resources is underutilized and therefore overpriced. Certain aspects of a data center may be, for example, over-specified and/or more robust than they need to be, while others are vulnerable to failure.

### SUMMARY

Embodiments of systems and methods of operating computing resources are described herein. In an embodiment, a computing module includes one or more racks, one or more cooling components, and one or more power distribution components. The racks include one or more servers and one or more tanks that hold liquid coolant for the servers. The one or more cooling components move a liquid to remove heat from the servers. The one or more power distribution components supply power to the servers. The one or more racks, one or more cooling components, and one or more power distribution components are commonly coupled to one another to be movable as a unit.

In an embodiment, a method of computing includes coupling one or more liquid cooling components and one or more power distribution components to one or more racks; supplying power from the power distribution components to servers in the racks; operating the servers in at least one of the racks to perform computing operations while the servers are submersed in a dielectric liquid coolant; and moving liquid in the liquid cooling modules to remove heat from the servers operating in the racks.

### BRIEF DESCRIPTION OF THE DRAWINGS

FIG. 1A illustrates an embodiment of an exemplary apparatus for cooling one or more independently operable data processing modules in a modular data center.

FIG. 1B illustrates one embodiment of an exemplary system for efficiently cooling a plurality of independently operable data processing modules.

FIG. 1C illustrates an alternative embodiment of an exemplary system for efficiently cooling a plurality of independently operable data processing modules.

FIG. 2 illustrates one embodiment of an integrated computing module includes racks with liquid-cooled servers, power distribution components, and liquid cooling components in a common container.

FIG. 2A illustrates a rack that can be used in a computing module in various embodiments.

FIG. 3 illustrates one embodiment of an integrated computing module includes racks with liquid-cooled servers, power distribution components, and liquid cooling components one a common base.

FIG. 4 illustrates one embodiment of an integrated computing module includes racks with liquid-cooled servers, power distribution components, and cooling components for circulating a secondary cooling liquid to racks a in cooling module.

FIG. 5A is a schematic top view illustrating liquid cooling in an integrated module having liquid-cooled servers.

FIG. 5B is a schematic top view illustrating electrical distribution in an integrated module having liquid-cooled servers.

FIG. 6 illustrates one embodiment of an integrated power distribution component/cooling component for providing cooling and electrical power to servers in multiple racks.

FIG. 7 illustrates a cross-sectional front view of a modular data center.

FIG. 8 illustrates a left side view of an exemplary tank

FIG. 9 illustrates a lift system for removing data processing modules from one or more tanks.

FIG. 10 illustrates a cross section view of an embodiment of a lift system for removing data processing modules from one or more tanks.

FIG. 11 illustrates one embodiment of a data center including integrated modules in shipping containers.

While the invention is described herein by way of example for several embodiments and illustrative drawings, those skilled in the art will recognize that the invention is not limited to the embodiments or drawings described. It should be understood, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION OF EMBODIMENTS

In various embodiments, power distribution components and liquid cooling components for racks with dielectric liquid coolant-submersed servers are integrated into one module. The single module may include all or a portion of the infrastructure components. In some embodiments, one or more liquid cooled data processing modules, cooling components, and power distribution components are integrated into a computing module. The computing module may be placed on a normal building floor.

In some embodiments, an integrated datacenter infrastructure system is in the form of a computing module is produced on a factory line. The computing module includes an optimized power infrastructure solution to a set of racks with servers in dielectric liquid coolant.

In some embodiments, a computing module includes all the infrastructure needed to operate a data center. For example, a single module could be designed for 100 kW. The end user may only have to supply a level floor. The computing module may, in various embodiments be delivered as a single piece or several sub modules, and include e.g. power distribution, cooling, and controls in a single package. If the end customer wants a 5 MW of data center capacity, for example, 50 100 kW Modules could be deployed and set next to each in a single room.

In some embodiments, a computing module is installed as a single unit onto the datacenter floor. The module may include several racks (four for example), a pump and heat exchanger component, and a power distribution component. The computing module may include everything necessary to distribute power to the various racks from a single power feed and water feed.

In some embodiments, a computing module is shipped as multiple different pieces. The pieces may be designed to be put together as a single unit. In some embodiments, a computing module is shipped with liquid coolant in one or more of the racks. In other embodiments, a computing module is shipped without liquid coolant in the racks, and the racks are filled with liquid coolant at the location at which the racks are to be operated.

In various embodiments, a plurality of servers is mounted vertically in a rack. The servers may be vertically removed and replaced from a rack with an open top. The servers may be mounted in an array, arranged horizontally. Each server may be removed without affecting the functionality of other servers in the rack or in the data center. Each server may operate independently of each of the servers.

In some embodiments, spacing and structure allow for accommodation of many different form factors, including but not limited to conventional rack mount servers normally used for air cooling. Servers mounted adjacently to each other to minimize upward flow around the servers or motherboards.

In some embodiments, dielectric fluid is pumped out of a rack, cooled by flowing through a heat exchanger, and pumped back into the rack. In other embodiments, the heat exchanger is located inside the rack. A secondary liquid circuit flows into the rack with dielectric fluid, and through a heat exchanger, cooling the dielectric fluid.

In one embodiment, a dielectric coolant flows out of a rack at an elevated temperature. A circuit may include a pump, heat exchanger, and measurement devices. A secondary circuit flows through the above heat exchanger, cooling the dielectric fluid, then flows outside and dissipates heat external to the room housing the dielectric-filled rack.

Systems and methods of cooling and operating electronic devices using liquid coolant-filled racks may be as described in US Patent Publication No. 2011/0132579 (the “'579 Publication”), by Best et al., published Jun. 9, 2011, which is incorporated by reference in its entirety as if fully set forth herein.

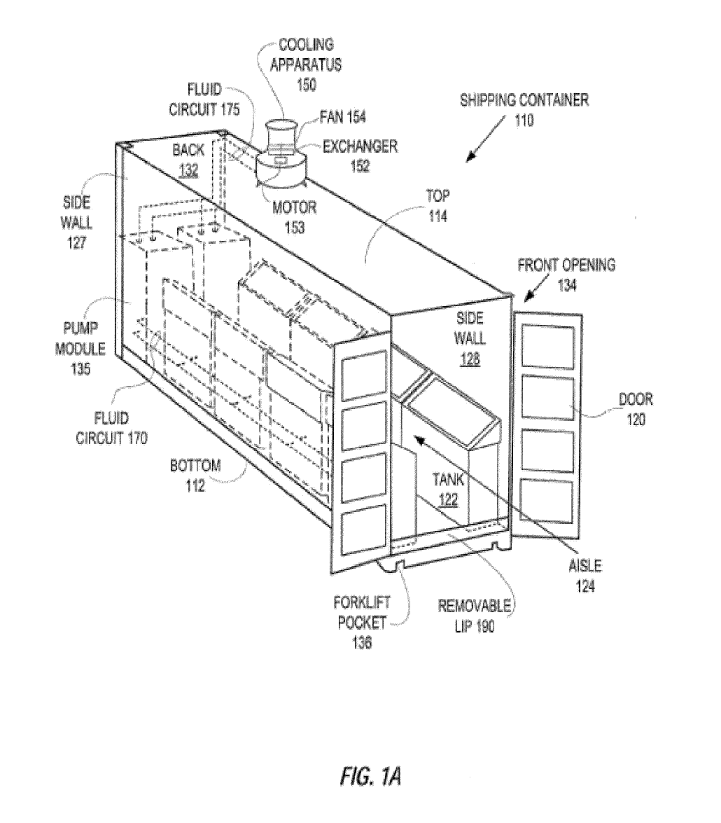

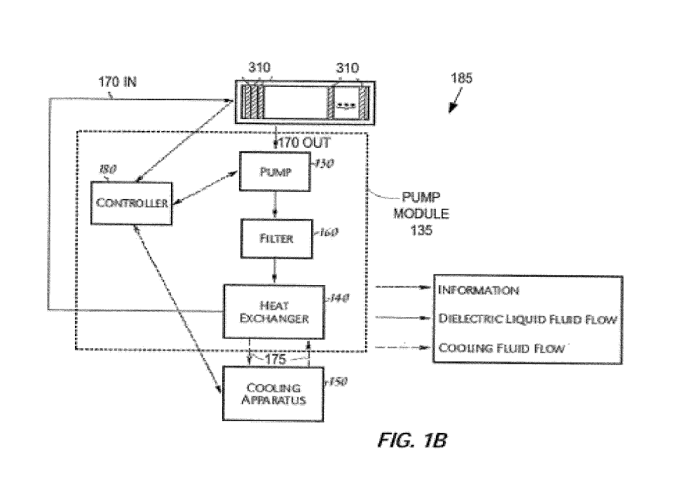

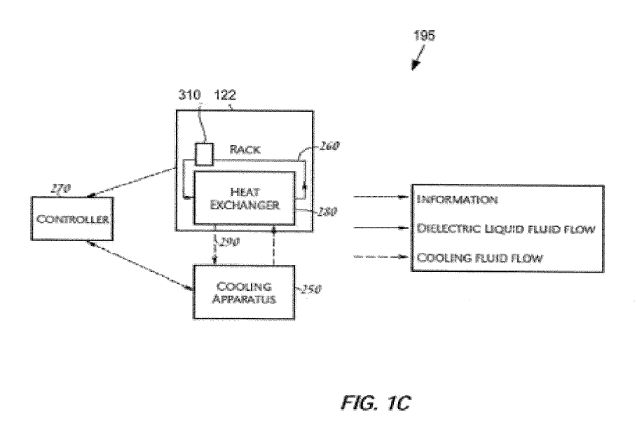

FIG. 1A depicts an exemplary, liquid cooled modular data center, for operating one or more independently operable data processing modules containing heat-generating electronic components arranged in one or more tanks. The modular data center includes a shipping container 110 having a bottom 112 and a top 114. Standard ISO shipping containers are 10, 20, or 40 ft. in length. Shipping container 110 has a back wall 132, opposing side walls 127 and 128, and a front opening 134, wherein front opening 134 is normally provided with a door 120.

Inside shipping container 110, a plurality of tanks 122 are provided, each tank 122 containing vertically mounted, independently removable and replaceable data processing modules. As shown in FIG. 1A, tanks 122 are arranged in two banks adjacent an aisle 124. The tanks may be arranged otherwise. For example, a single bank of tanks 122 may be installed in the center of shipping container 110 with aisles on either side of tanks 122. Or a single bank of tanks 122 may be installed against a wall of shipping container 110, for example.

Referring now to FIG. 1B, shipping container 110 may include a cooling system 185 for transferring heat from data processing modules 310. The liquid coolant heated by data processing modules 310 is fluidly coupled through suitable piping or lines to a pump 130, which pumps the heated liquid coolant through suitable piping or lines to a heat exchanger 140 associated with a heat-rejection or cooling apparatus 150. In some embodiments, heat exchanger 140 is remotely or distally located from tank 122 and/or shipping container 110. Heat exchanger 140 rejects the heat from the incoming heated liquid coolant and fluidly couples the cooled liquid coolant through a return fluid line or piping 170 back into the tank 122. Thus, at least a portion of the liquid coolant completes a fluid circuit through the data processing modules 310 in tank 122, pump 130, heat exchanger 140, and back into tank 122. The heat rejected from the heated liquid coolant through the heat exchanger 140 may then be selectively used by alternative heat rejection or cooling apparatus 150 to dissipate, recover, or beneficially use the rejected heat depending on the different environmental conditions or data processing modules 310 operating conditions to which the system is subject.

Referring now to FIG. 1C, an embodiment of an alternative cooling system 195 is illustrated for cooling data processing modules 310. Unlike the cooling system 185, heated liquid coolant does not flow outside the tank 122. Instead, one fluid circuit 260 of the flowing liquid coolant is completely internal to the tank 122. A thermal coupling device 280, such as a heat exchanger, is mounted within the tank 122 within the fluid circuit through the data processing modules 310, so that at least a portion of the heated liquid coolant flow exiting the data processing modules flows through the thermal coupling device 280. Cooled liquid coolant exits the coupling device 280 and at least a portion of the cooled dielectric coolant circulates in the internal fluid circuit 260 back through the data processing modules 310.

Cooling systems 185 (FIG. 1B) and 195 (FIG. 1C) include a computer controller 180 with suitable applications software for implementing various embodiments. A detailed description of controller 180 is included in international published patent application WO 2010019517 which is incorporated by reference, as stated herein above. In some embodiments, temperatures of operation may be established and maintained as set forth in the WO 2010019517 application.

Referring now to FIGS. 1A and 1B, cooling apparatus 150, which provides an evaporative final heat exchanger 152 and a motor 153 driven fan 154 for forcing air flow through final heat exchanger 152, is located sufficiently far away from tanks 122 to enable adequate heat dissipation at exchanger 152 to cool the heated liquid in loop 175. The resulting heat may be vented to the ambient outside environment. Alternately, the resulting heat may be beneficially used, as described in PCT patent application WO 2013022805. The cooled liquid is then recirculated through the return pipe in loop 175 to cool the liquid coolant in loop 170 which, in turn, cools the data processing modules 310 in tanks 122. (Heat exchanger 152, fan 154 and motor 153 are shown schematically, are not to scale and may be arranged differently than shown.) In one or more embodiments, cooling apparatus 150 is mounted on the exterior top of container 110. This is advantageous because it allows deploying the data center contained by shipping container 110 as a single “block,” which is faster. With cooling tower 150 physically attached to container 110, structural support is provided by container 110, eliminating the need to pour concrete supports for cooling towers.

Although one cooling apparatus 150 is shown, more than one may be provided in various embodiments. For example, one cooling apparatus 150 may be provided for each bank of tanks 122. Further, cooling loops 175 may be arranged, and each cooling apparatus 150 may be sized, so that a plurality of cooling apparatus 150 may provide backup cooling for one other. Cooling apparatus 150 need not be attached to the shipping container.

As shown in FIG. 1A, a module 135, which may include at least elements as shown in FIG. 1B, for example, is provided for tanks 122, according to one or more embodiments. That is, according to one or more embodiments, each pump module 135 may include primary and secondary pumps 130 (and associated pump motors) connected to filter 160 and liquid coolant heat exchanger 140 of at least one bank of tanks 122 via fluid circuit 170 such that primary and secondary pumps 130 may function independently of one another for backup purposes, with electrically isolated pump 130 motors. According to one or more embodiments, primary pump 130 motor is controlled by variable speed controller 180 for regulating temperature of coolant loop 170 by varying liquid coolant flow, whereas secondary pump 130 motor is fixed-speed and controlled by on-off control.

Also provided is a module 135 for evaporative cooling apparatus 150 according to one or more embodiments, which includes a controller for control ing a pump motor in loop 175, which may be on-off control or variable speed control, according to one or more embodiments, and includes a controller for fan 154 motor 153, which may be like controller 180 of FIG. 1B, for example, but for regulating fan 154 speed of evaporative cooling apparatus 150 in order to control temperature of loop 175 by varying air flow over evaporative final heat exchanger 152. A pump, motor controller and cooling water loop may also be provided to run water over the exterior of heat exchanger 152 for additional cooling.

According to one or more embodiments, where cooling tower 150 is integrated with container 110, as shown in FIG. 1A, for example, liquid coolant of loop 170 may be run directly to heat exchanger 152 of cooling tower 150 in a closed loop, rather than providing separate loop 175. A pump and cooling water loop may be provided to run water over the exterior of heat exchanger 152 during hot periods in addition to the air drawn through exchanger 152 by fan 154, while during cold periods the water is not needed because air through exchanger 152 provides sufficient cooling. This dramatically reduces the amount of water used for cooling.

Controllers 180 may be interfaced via a network with a master controller for which a single dashboard is provided, according to one or more embodiments, which is for displaying and controlling water flow in one or more loops 175 through one or more cooling towers 150, fan power for air flow across the one or more heat exchangers of 152 one or more cooling towers 150, and liquid coolant flow in one or more loops 170 for tanks 122. Preferably, the master controller optimizes all elements for minimum power consumption of the system while maintaining sufficient cooling. The network controller performs diagnostic testing of each element separately for functionality and reports the functionality back to a single user. This single management point makes the system more reliable and more efficient, since the master controller can obtain maximum efficiency for all components. In some embodiments, control is carried out as described in the '579 Publication.

Insulation is provided for exterior walls 127, 128 and 132 of container 110, as well as for doors 120, according to one or more embodiments. The insulation may include a spray on coating added to the inside or outside of container 110 and may include dirt piled on top 114, possibly with grass growing on the surface, since dirt and grass provide excellent insulation. This reduces the amount of solar heating to container 110 during the summer, making it easier for people to work therein and service the data processing modules 310 and other equipment. The lower ambient temperature also makes the power distribution equipment more reliable. Additional safety equipment may include a non-slip floor, an emergency exit, motion detection and other security.

### Integrated Computing Module

In some embodiments, a module including dielectric coolant liquid filled tanks is installed as a single unit onto the datacenter floor. The module may include several racks (for example, four racks), a pump and heat exchanger component, and a power distribution component. The module may include everything necessary to distribute power to the various racks from a single power feed and water feed.

In some embodiments, power distribution equipment, cooling, containment, assisted lift, and insulation are combined in a system to yield a high efficiency, low cost system.

A control module may connect into a larger monitoring system, such as a building management system, data center management system, stand alone or other manner of operations. In some embodiments, the control module controls and monitors external components, such as building water pumps, cooling towers, remote battery backup components, other modules, remote power generators, security, room PDUs, rack PDUs, and other systems.

In some embodiments, a module includes battery backup power device for either AC (e.g. UPS) or DC. The battery backup device would provide power output to power distribution ports from the main feed to battery backup.

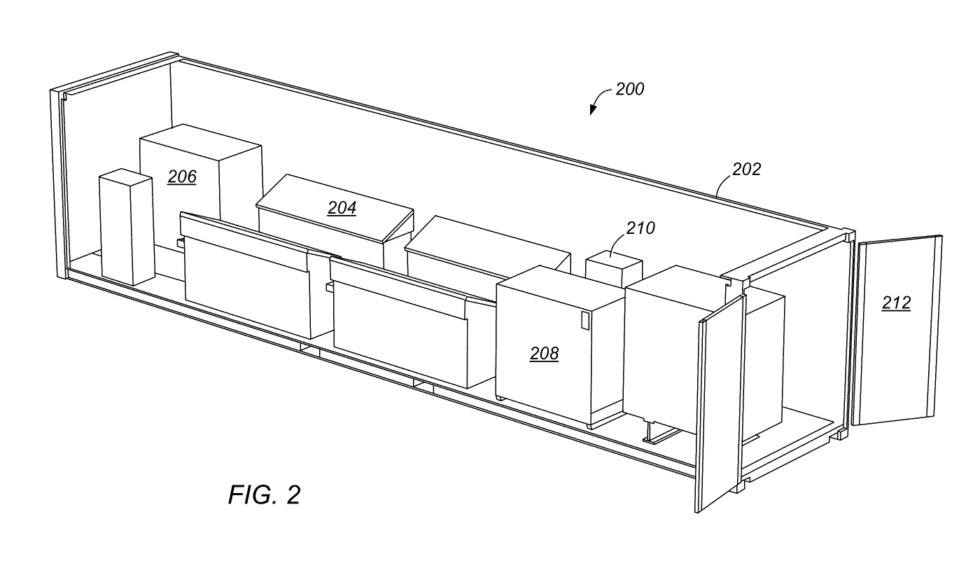

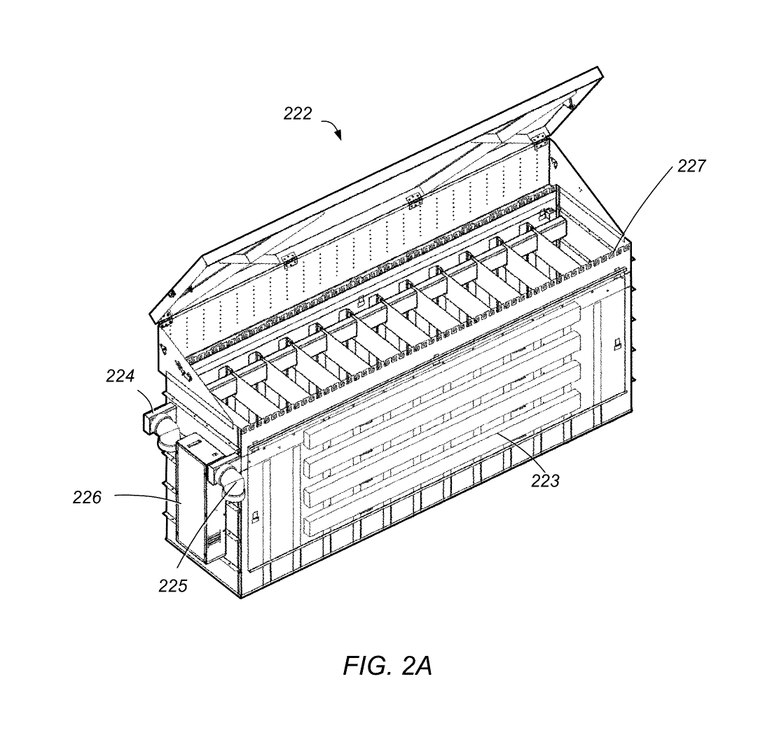

FIG. 2 illustrates one embodiment of an integrated computing module including racks with liquid-cooled servers, power distribution components, and liquid cooling components in a common container. Computing module 200 includes container 202, racks 204, pump module 206, room power distribution unit 208, and heat pumps 210. In FIG. 2, the near wall and top of container 202 are omitted for illustrative purposes. Doors 212 provide on container 202 allow for access to components in container 202.

Racks 204, pump module 206, room power distribution unit 208, and heat pumps 210 may be attached (for example, bolted down) to the floor of container 202.

A single or multiple power feed(s) may feed electronic systems in module 200. The power feed may be at voltages such as 208, 240, 277, 480 VAC, or DC voltages in the case of systems using DC battery backup or distribution system. A single feed may go into a power distribution center (e.g., room PDU 208), or multiple power distribution centers or subpanels, to connect all required loads and/or if redundancy is required.

The power distribution system (e.g., room power distribution unit 208) may include a transformer that adjusts (and, if required, isolates) the input AC voltage to the required load voltages. The power may be distributed into multiple ports. Each or a group may include a breaker. Each port may connect, for example, to a rack-level power rack distribution device (e.g. outlet strip) attached to the racks and/or the liquid-filled rack system. Alternatively, loads may be wired into the distribution system directly or other manner of connection. In some embodiments, power distribution components may adjust DC power from a distribution voltage to a load voltage.

Pump module 206 and heat pump 210 may provide cooling of electronic components of computing module 200. Pump module 206 may circulate liquid to remove heat from servers operating in racks 204, room PDU 208, or both. Heat pumps 210 may remove heat from air inside container 202 and reject the heat outside of container 202. The heat pumps may cool the ambient air in the data center, such that the space is usable and power distribution equipment does not overheat. Use of heat pumps may be as further described below.

FIG. 2A illustrates a rack that can be used in a computing module in various embodiments. Rack 222 includes power distribution units 223, liquid coolant inlet port 224, liquid coolant exit port 225, and rack control module 226.

Rack 222 includes a cable management system. Cable management system includes cable management rails 227. Each of cable management rails 227 includes a series of cable guides. The cable guides may be used to guide and support power cables or data cables for each of the servers in rack 232. In some embodiments, cables and cable connector receptacles remain above the surface level of the coolant in the rack.

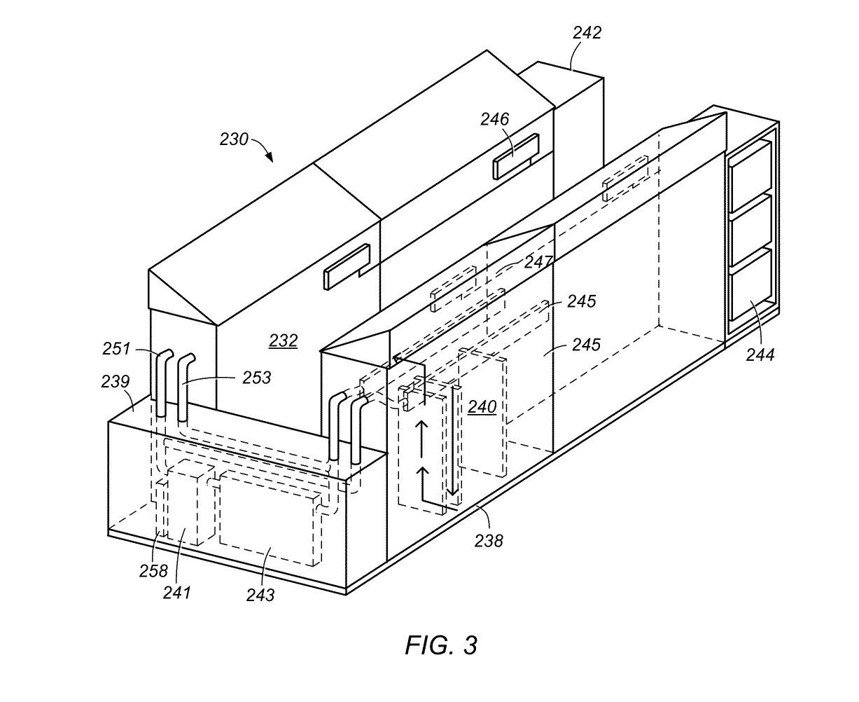

FIG. 3 illustrates one embodiment of an integrated computing module including racks with liquid-cooled servers, power distribution components, and liquid cooling components on a common base. Liquid-cooled servers, power distribution components, and liquid cooling components may ship together as an assembly. In some embodiments, power distribution components and liquid cooling components are sized for the servers to be operated in the computing module.

Computing module 230 includes racks 232, power distribution components 234, cooling component 236, and base 238. Racks 232, power distribution component 234, and cooling component 236 are supported on base 238. Each of racks 232 includes servers 240. Servers 240 are vertically arranged in racks 232. In some embodiments, any of servers 240 may be removed from rack 232 without removing or disturbing operation of the other servers when the top is removed or folded back.

Power distribution component 234 includes transformer 242 and power distribution units 244. Power distribution units 244 may feed power to cabinet power distribution units 246 on each of racks 232.

Cooling module 239 includes pump module 241, heat exchanger 243, coolant supply line 251, coolant return line 253, water inlet line 254, water return line 256, and controller 258.

A computing module of several liquid submersion cooling racks and one pump module (such as computing module 230) may maximize efficiency and data center floor space. Each block of four racks may have its own control system that optimizes coolant flow in real-time for the given heat load while monitoring the cooling system across more than twenty-five parameters.

In some embodiments, OEM and ODM servers are installed vertically into rack 232. Racks 232 may support servers from any manufacturer, in, for example, Standard 19″ or Open Compute Standard form factors. Servers may be lowered vertically into the liquid-filled rack. PDUs may be mounted to the front or the back of the rack.

Cooling component 239 may include coolant pumps, filters, and coolant-to-water heat exchangers. The pump module is responsible for circulating the liquid coolant and drawing heated coolant through heat exchangers to remove server heat from the racks. The pump module may then filters the coolant and returns the reduced temperature coolant to the liquid submersion cooling rack. The pump module may establish a stable and uniform cooling environment for servers 240 that is controlled to ±1° C. throughout each of racks 232.

Cooling component 239 may receive power connectivity and water connectivity from the facility. Cooling component 239 may be configured to use virtually any form of water available in a data center facility. In some embodiments, a pump module includes an independent secondary system for backup. If the primary pump should fail, the secondary kicks on instantaneously and cooling will continue undisturbed. Although pump module 239 is shown for illustrative purposes at the end of rows of racks 232, depending on the space requirements of the facility, the pump module may be installed adjacent to the racks, under the floor, or in the data center periphery.

Coolant may flow in and out of racks 232 at the ends of racks 232 (coolant lines for the rearmost pair of racks may also be coupled to cooling component 239, however, they are omitted from FIG. 3 for clarity.) In one embodiment, the overall path of coolant flow is as shown in FIG. 3. Coolant coming into rack 232 may be distributed across the length of rack 232 in manifold 245 and then channeled downward (for example, via ducts, barriers, or baffles) to the bottom of rack 232. From the bottom of rack 232, coolant may flow up between servers 240 until it reaches the top of servers 232 (and near the surface of liquid coolant), increasing in temperature as heat is transferred from heat producing components on the servers. Coolant may then be drawn out of rack 232 through manifold 247 and returned to heat exchanger 243. In some embodiments, augmentation devices (such as nozzles, pumps, or fans) are provided at one location, or at multiple locations, in racks 232. For example, a nozzle may be provided at the bottom of each of servers 232.

In some embodiments, controller 258 provides diagnostics and controls for computing module 230. The control system optimizes coolant flow to provide the most efficient coolant flow at all times for the given heat load. The control module may also initialize the backup system and provide alerts in the event of system downtown or failure. In various embodiments, controller 258 may provide temperature analysis, pressure and coolant level verification, power consumption, smart monitoring, and diagnostics. Controller 252 outputs may include log files of the above parameters, e-mail and SMNP diagnostic alerts, and hourly status condition updates. This information may also be made available via a network as well as a secure internet portal.

In certain embodiments, racks, cooling components, and power distribution components of a computing module are mechanically linked with one another instead of, or in addition to, being commonly mounted on a base.

In one embodiment, a single high voltage power feed goes into one or more power distribution units (PDU). A transformer reduces the power from high voltage to a lower voltage (for example, 480 VAC to 208 VAC in the US). The power distribution may include protection against power spike and/or line noise, such as transient voltage surge suppression. The reduced voltage lines (e.g., 208 VAC) may be distributed into multiple different feeds.

Each feed may be connected to a cabinet distribution unit (CDU) at the rack. Each feed may include a breaker and/or current monitoring. In certain embodiments, one or more of these components are separated out (transformer, transient voltage surge suppression (“TVSS”), and others), rather than housed inside of a power distribution unit.

In some embodiments, CDUs are included and mounted to each rack. The CDUs may be passive, active, or combination thereof. An active CDU may include power level measurement of voltage and current for each plug (normally where the server plugs into) and the capability to turn each port on or off. Monitoring may be performed by control system for the module. Monitoring may include values for CDU, PDU, or both.

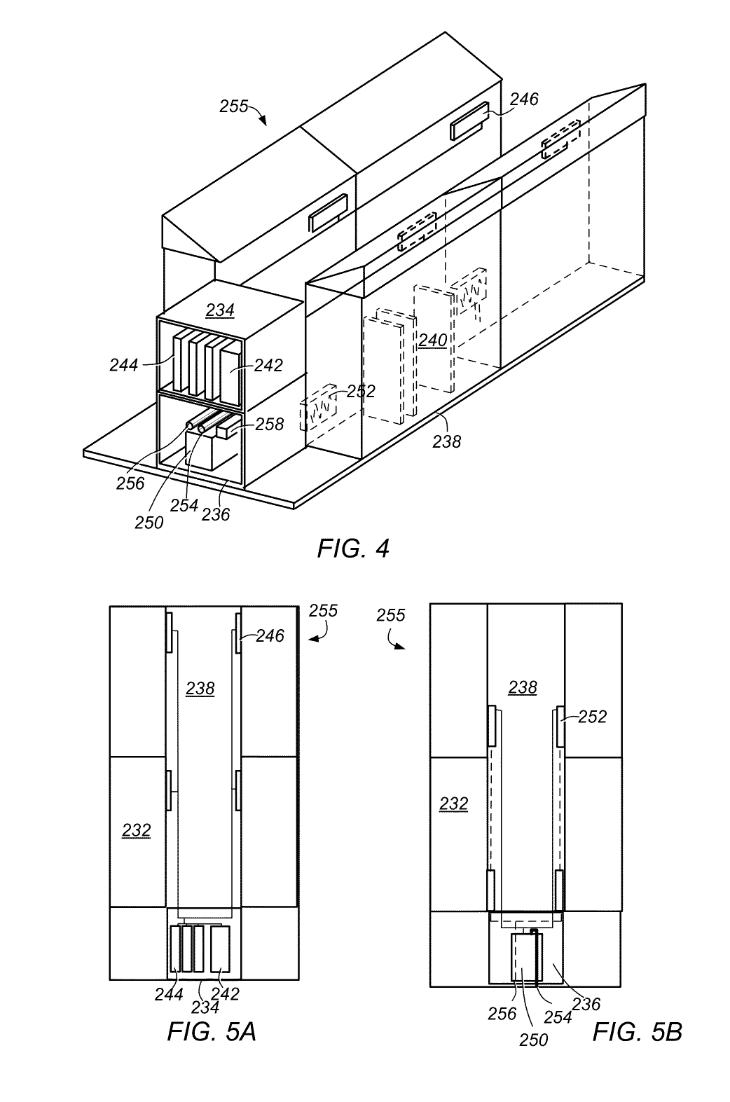

FIG. 4 illustrates one embodiment of an integrated computing module includes racks with liquid-cooled servers, power distribution components, and cooling components for circulating a secondary cooling liquid to racks a in cooling module.

Computing module 255 includes racks 232, power distribution component 234, cooling component 236, and base 238. Racks 232, power distribution component 234, and cooling component 236 are supported on base 238. Each of racks 232 includes servers 240. Servers 240 are vertically arranged in racks 232. In some embodiments, any of servers 240 may be removed from rack 232 without removing or disturbing operation of the other servers when the top is removed or folded back.

FIG. 5A is a schematic top view illustrating electrical distribution in an integrated module having liquid-cooled servers. Power distribution component 234 includes transformer 242 and power distribution units 244. Power distribution units 244 may feed power to cabinet power distribution units 246 on each of racks 232.

In some embodiments, two or more of power distribution units 244 are redundant with one another. In such case, service personnel can remove and replace one of power distribution units 244 without interrupting operation of servers in racks 232.

In some embodiments, a computing module includes an integrated monitoring device. The integrated monitoring device may monitor various characteristics of power and cooling. An integrated monitoring device may measure, for example, any or all of the following components or subcomponents:
Monitoring the amount of current or voltage to each port (and/or monitoring the output from a PDU)
On/off relays for each power port
Temperature fuse integrated into the power input, shutting power off the ambient or oil temperature gets too high
Fire suppression
Security

FIG. 5B is a schematic top view illustrating liquid cooling in an integrated module having liquid-cooled servers. Cooling component 236 includes pump module 250, heat exchangers 252, water inlet line 254, water return line 256, and controller 258.

Pump module 250 may move liquid coolant, water, or both such that heat is transferred from liquid coolant in racks 232 into a water stream (for example, by way of heat exchangers 252). Heat may be carried away from computing module 230 by way of return water line 256.

A module may be configured to have bays for each component, such as some designated for power distribution, pumping, battery backup, etc. There may be multiple bays designated for each component, even when only one is necessary for operation of the system. For example, if there are two power distribution ports and only one is in use, a replacement power distribution system could be dropped into the second power distribution bay and while the first power distribution system is removed. The result is that the power distribution module can be replaced without servers in the racks losing power.

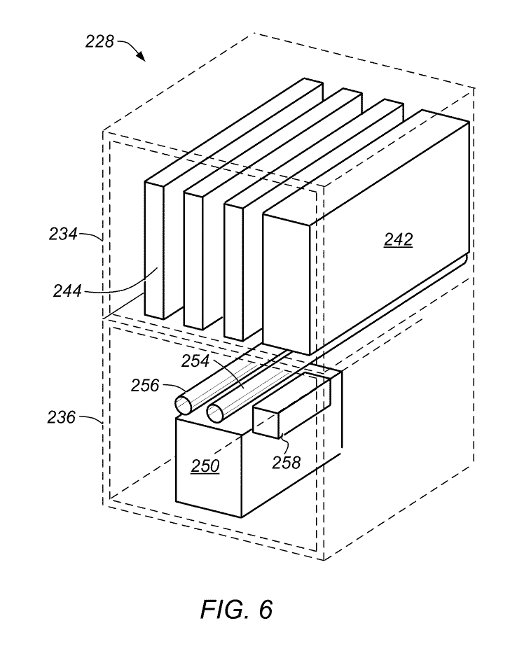

FIG. 6 illustrates one embodiment of an integrated power distribution component/cooling component for providing cooling and electrical power to servers in multiple racks. Power distribution/cooling system 228 includes power distribution component 234 and cooling component 236. Each of transformer 242, power distribution units 244, and pump module 250 may be installed in its own bay in power distribution/cooling system 228. Each of the individual components, such as power distribution, pumps, etc. may be removed individually for maintenance.

### Water Source Heat Pump

In some embodiments, a water source heat pump cools room air on one side of a container (the air inside of the shipping container) and dumps heat into a water loop (the cooling tower loop in this case). The system may use a refrigeration/compressor cycle. Interior air may be reduced to a lower temperature, 37 degrees C. for example. A cooler temperature may extend the capability and reliability of the electrical distribution in the room, electric motors in the cooling system, and motor controllers in the cooling system The water source heat pump may connect to the water loop hooked into the container and dumps heat to the same water circuit that the rack systems dump heat into. The water source heat pump may be monitored for ongoing reliability, including power consumption, refrigerant charge, and other operating conditions.

The exterior ports into the container may be minimized to seal the container from the outside. This makes the environment more robust and better able to operate in harsh environments such as a desert or other extreme climates. In addition, without air moving in and out of the container (basically sealing it), fires may self-extinguish due to a lack of oxygen.

The water coming out of the cooling tower may be significantly lower than ambient temperature. As such, the water which the room air conditioning discharges heat into is at a lower temperature than it would be if it discharged to outside air. Since the discharge temperature is lower, the WSHP may be more efficient and use less power.

In certain embodiments, heat is blown through a radiator into the room. Fluid flows in the radiator and is the same water that flows into the system used to cool the servers.

In some embodiments, a cooling tower is physically attached to the top of the computing module to be deployed as a single system. Coolant may be run to the tower directly by way of a closed loop cooling tower. The closed loop cooling tower may include dielectric cooling running through coils in the tower. During hot periods of the year, the exterior of the coils may have water and air pouring over them during hot periods of the year. During cold periods of the year, water may not be needed (for example, air may be sufficient to cool the dielectric). By selectively operating the cooling tower based on environmental conditions, the amount of water used may be reduced relative to a conventional tower.

In some embodiments, a computing module includes safety and security measures, such as a non-slip floor, emergency exit, and motion detection system.

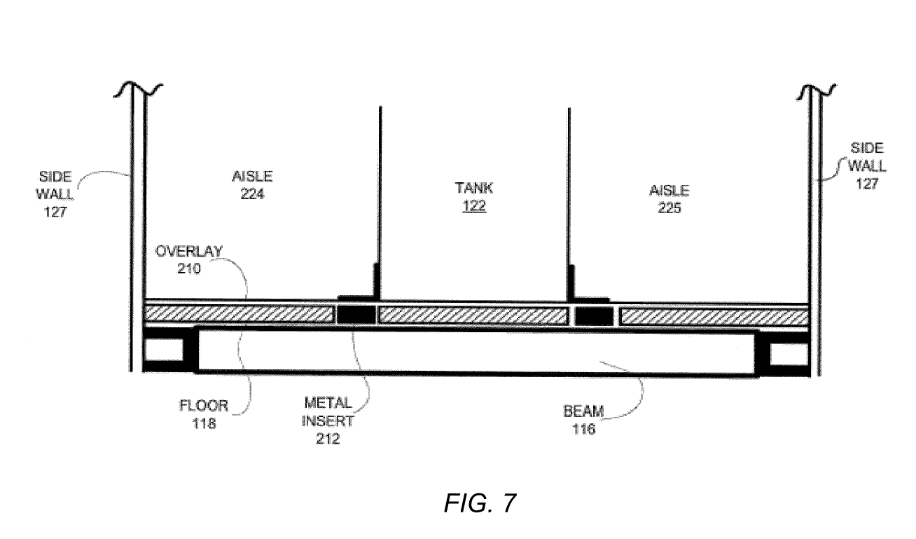

Referring now to FIG. 7, a front plan cross section view of the modular data center is presented, according to an embodiment. As depicted in FIG. 7, tanks 122 are arranged in a single bank in the center of shipping container 110 with aisles 224 and 225 on either side of tanks 122, although this is just one of other possible arrangements, as previously stated. Overlay 210, which may be sheet metal, is provided on top of floor 118 of shipping container 110 and is sealed at least to side walls 127 and 128 and back wall 132 to create a liquid tight barrier to hold liquid coolant in the event of a leak from tank 122 or from lines of the cooling system carrying the liquid coolant as hereinafter described. Other materials may be provided for overlay 210, such as plastic or other suitable material, and overlay 210 may also be sealed to front 134 of shipping container 110.

According to one or more embodiments, a front lip 190 is provided at the threshold of front opening 134 (lip may, however, be provided at any doorway), which requires a user to step over lip 190 when entering shipping container 110. Lip 190 is preferably sealed in removable fashion to walls 127 and 128 and overlay 210, such that the seal provided by lip 190 is sufficient to keep any spilled liquid coolant from coming out of container 110 via front opening 134. The top edge of lip 190 is a sufficient height above overlay 210 such that the volume defined by the exposed surface area of overlay 210 and height of top edge of lip 190 is at least 110% of the volume of liquid coolant in one tank 122.

Lip 190 is of a suitable material for sealing. In one or more embodiments, lip 190 is substantially rigid metal or plastic, for example, wherein lip 190 seals in a removable fashion so that removal enables rolling tanks 122, pumping modules 135 and other equipment in and out of container 110. Lip 190 may alternatively include a soft material such as a deformable foam or plastic that deforms when a heavy object rolls over it but pops back into place afterwards, such as a Build-a-Berm barrier, which is commercially available by Pig. (“Build-a-Berm” and “Pig” are trademarks of New Pendulum Corp.) The seal by lip 190 where lip 190 interfaces walls 127 and 128 and overlay 210 may be maintained at least partly by pressure of lip 190 against walls 127 and 128 and overlay 210 and maybe facilitated also by a gasket against the surface of lip 190 that faces walls 127 and 128 and overlay 210. The seal may be also or alternatively enhanced by a sealing compound, such as a nitrile rubber, for example.

In one or more embodiments, edges of overlay 210 (e.g. edges at walls 127, 128 and 132 and at front 135) may be turned up and joined, such as by welding, adhesive, gaskets, etc., wherein the turned up and joined edges of overlay 210 provide sides for the container, so that overlay 210, including its sides, provides a liquid tight container. More generally, sides may be provided at edges of overlay 210 (i.e., edges at walls 127, 128 and 132 and at front 135) in any suitable manner, which may include berm-type sides, so that overlay 210, including its sides, provides a liquid tight container. In this case, the edges or sides of overlay 210 are not necessarily sealed to container 110, although they may be.

Shipping container 110 comprises at least one beam 116 integrated into the bottom 112 and a floor 118 installed on top of the at least one beam 116. Floor 118 is typically a wooden floor, such as 28 mm plywood, for example, to which fasteners may be secured and that is disposed above bottom 112 and supported by the at least one beam 116. Alternatively, floor 118 may include other materials such as plastic or metal.

One or more data processing modules in one or more tanks 122 containing liquid coolant are installed on top of overlay 210. Tanks 122 are secured so they are fixed in position within container 110, which may be by attaching fasteners (e.g., bolted) through overlay 210 and floor 118, into beam 116, which is integrated into bottom 112 of shipping container 110. Penetrations through overlay 210 are sealed, such that liquid cannot leak through. In some cases, a metal insert 212 may be put in place between the beam and tanks 122. Tanks 122 may also be secured by other means to overlay 210, such as by welding or adhesive, for example.

In the embodiment depicted in FIG. 7, beam 116 runs essentially from one sidewall 127 to the other sidewall 128 and has an “I” shaped cross-section profile, which is obtained by two rails on each end facing sidewalls 127 and 128, where the end rails are connected to a rail in the middle, as shown. Floor 118 is supported by a plurality of such beams 116 in the depiction of FIG. 7, although only one such beam 116 is visible in the figure. Beam 116 may have other configurations, including non-I shaped profiles. Rather than providing beams 116 running from one sidewall to the other, one or more beams 116 may be provided running lengthwise, that is, from front 134 to back 132.

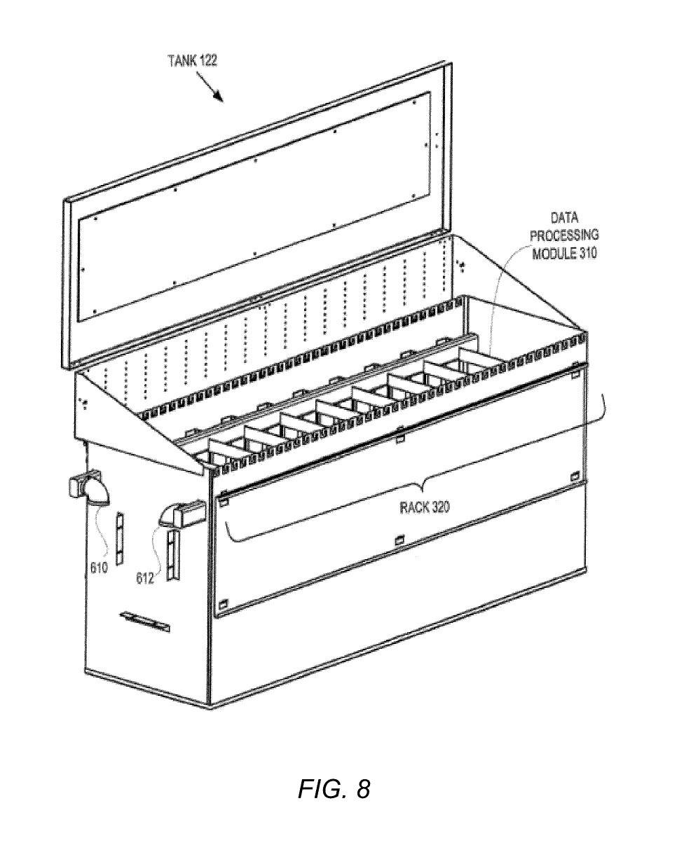

Referring now to FIG. 8 a side view of tank 122 is depicted. Tank 122 may optionally have a hinged or removable lid (shown open in FIG. 8) or an open top. Tank 122 may be fabricated of steel, a sufficiently strong plastic that is compatible with the liquid coolant used as a cooling medium, or other suitable material. Tank 122 may face upward with an open top to form an open interior volume. Tank 122 may contain a plurality of independently operable data processing modules 310 mounted vertically and independently removable and replaceable from tank 122. Each data processing module 310 is independently removable and replaceable without affecting the position or operation of other data processing modules. The independently operable data processing modules 310 may be mounted in an array arranged horizontally and immersed at least partially in liquid coolant.

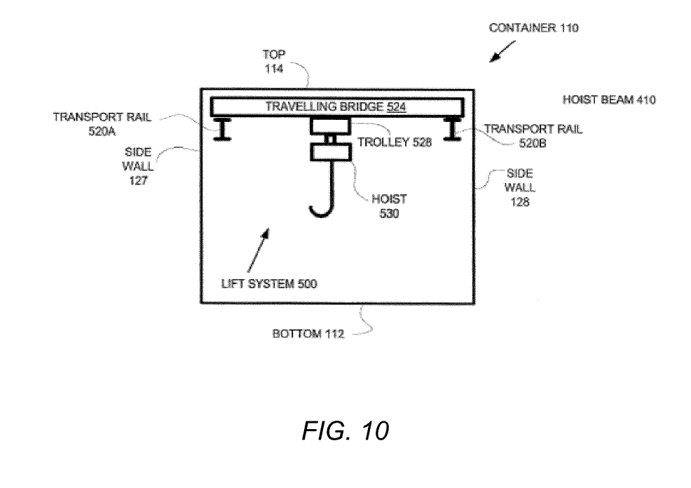

Referring now to FIG. 10 in conjunction with FIG. 1A, a lift system 500 is provided in container 100 for removing data processing modules 310 from one or more tanks 122, in one or more embodiments. In this embodiment, transport rails 520A and B are mounted fixedly to side walls 127 and 128, with traveling bridge 524 spanning transport rails 520A and B on rollers (not shown), so that traveling bridge 524 is configured for moving the length of transport rails 520A and B, which may be the length of container 110 from front 134 to back 132 or may be the width from side wall 127 to side wall 128, depending on orientation of lift system 500 within container 110. (It should be understood that transport rails 520A and B may alternately be mounted in other ways within container 110, such as directly to top 114, for example.) Trolley 528 is configured to roll along the length of traveling bridge 524, i.e., from one transport rail 520A to the other 520B, with hoist 530 suspended from trolley 528. Hoist 530 has a cable and hook configured to be attached to data processing module 310 so that hoist 530 can raise and lower data processing module 310 from tank 122, which is filled with liquid coolant. When hoist 530 has raised a data processing module 310 out of tank 122, trolley 528 can roll along traveling bridge 524 and traveling bridge 524 can roll along transport rails 520A and B to move the data processing modules 310 to a different location. Thus, a user may position hoist 530 over a data processing module and pick the data processing module out of the liquid coolant to perform data processing module maintenance, for example.

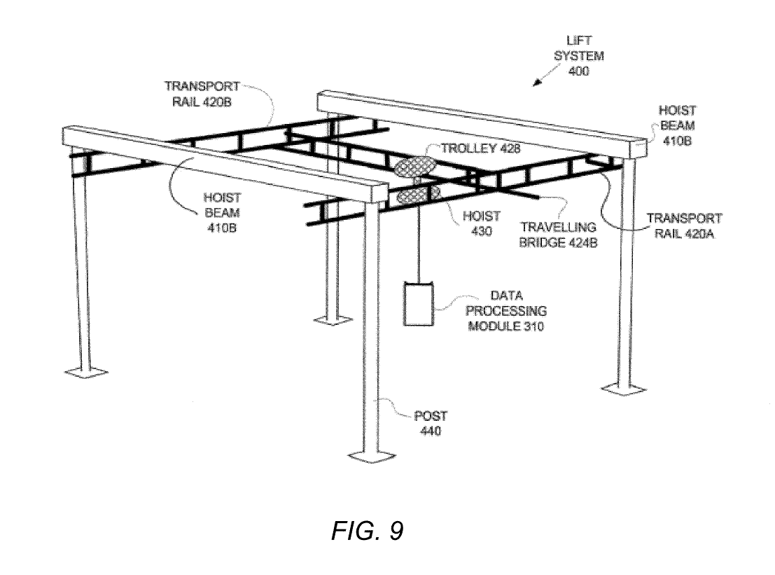

Referring now to FIG. 9 in conjunction with FIG. 1A, a lift system 400 provided in container 110 for removing data processing modules 310 from one or more tanks 122 is depicted, according to one or more embodiments, wherein hoist beams 410 are rigidly fixed to and supported by posts 440, which may stand upon overlay 210 (FIG. 7) and may be fixed thereto or to floor 118 (FIG. 7) or beam 116 (FIG. 7). Transport rails 420A and B are mounted fixedly to hoist beams 410A and B, with a traveling bridge 424 spanning transport rails 420A and B on rollers (not shown), so that traveling bridge 424 is configured for moving the length of transport rails 420A and B, which may be the length of container 110 from front 134 to back 132 or may be the width from side wall 127 to side wall 128, depending on the orientation of lift system 400 within container 110. (It should be understood that transport rails 420A and B may alternately be mounted directly on posts 440 without hoist beams 410A and B.) Trolley 428 is configured to roll along the length of traveling bridge 424, i.e., from one transport rail 420A to the other 420B, with hoist 430 suspended from trolley 428. Hoist 430 has a cable and hook configured to be attached to data processing module 310 so that hoist 430 can raise and lower data processing module 310 from tank 122, which is filled with liquid coolant. When hoist 430 has raised a data processing module 310 out of tank 122, trolley 428 can roll along traveling bridge 424 and traveling bridge 424 can roll along transport rails 420A and B to move the data processing modules 310 to a different location. Thus, a user may position hoist 430 over a data processing module and pick the data processing module out of the liquid coolant to perform data processing module maintenance, for example.

In one or more alternative embodiments, a gantry crane configuration is provided for lift system 400, wherein posts 440 are not fixed to the container, but rather include rollers, with transport rails 420A and B extending less than the entire length or width of container 110. Thus, according to one such gantry crane configuration, posts 440 roll from front 134 to back 132 or from side wall 127 to side wall 128, depending on orientation of lift system 400 within container 110.

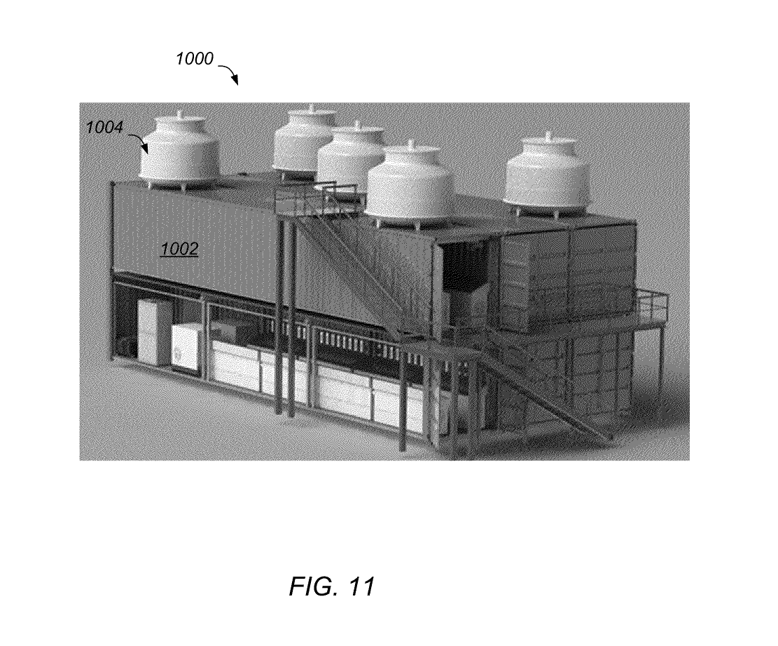

In some embodiments, two or more computing modules are combined to form a data center. Some or all of the computing modules may include integrated modules with racks, power and cooling. In on embodiment, each computing module is provided in a container (for example, an ISO shipping container). In other embodiments, some or all of the integrated computing modules are not in shipping containers (for example, mounted on common base.) A data center may include two or more computing modules stacked on another, next to one another, or combinations thereof. In certain embodiments, some or all of the container include their own cooling tower. FIG. 11 illustrates one embodiment of a data center including integrated modules in shipping containers. Data center 1000 includes computing modules 1002. Some of container modules 1002 include their own cooling towers 1004.

In some embodiments, mounting members of a rack are configured to mount the servers closely adjacent to one another in the server rack to restrict the flow of the dielectric liquid coolant between the vertically-oriented servers, such that the flow of the dielectric liquid coolant through the servers is enhanced

In some embodiments, a temperature of a liquid coolant may be monitored and/or controlled. Methods of monitoring and controlling temperature of the oil may be as described in the '579 Publication”), by Best et al., published Jun. 9, 2011, which is incorporated by reference in its entirety as if fully set forth herein.

In some embodiments, flow through the servers in augmented using augmentation, such as nozzles, fans, or pumps. A separate augmentation device may be included on each node, every other node, each row of nodes, or other frequency. The '579 Publication describes apparatus and methods using augmentation devices in various embodiments.

In some embodiments, liquid coolant may be removed through the top of the rack. Liquid coolant may be reintroduced after having been cooled (for example, by passing the liquid coolant through a heat exchanger outside of the rack. The '579 Publication describes apparatus and methods for removing liquid coolant from the top of a rack in various embodiments.

In various embodiments described herein, computing modules are shown as having four racks. Computing modules may nevertheless in various embodiments have any number of racks. In one embodiment, a computing module has one rack.

In various embodiments described herein, a system has been described as holding motherboard assemblies in a submersed or partially submersed condition. A system may nevertheless in various embodiments hold other types of circuit board assemblies or components in a partially submersed condition.

As used herein, the terms “or” is intended to cover a non-exclusive inclusion. That is, “or” includes both meanings of both “or” and “and/or.”

The terminology used herein is for the purpose of describing particular embodiments only and is not intended to be limiting of the invention. As used herein, the singular forms “a”, “an” and “the” are intended to include the plural forms as well, unless the context clearly indicates otherwise.

As used herein, the term “data processing module” generally refers to one or more computing devices running software configured to receive requests, typically over a network. A data processing module may include one or more servers connected to a network and running software configured to receive requests from other computing devices on the network, which may include other servers, and desktop and mobile computing devices, including cellular phones. Such data processing modules typically include one or more processors, memory, input/output connections to a network and other electronic components, and may include specialized computing devices such as blade servers, network routers, data acquisition equipment, disc drive arrays, and other devices commonly associated with data centers.

As used herein, the term “shipping container” refers to a commercially available shipping container that is used to transport goods on ships, trains and trucks, and which may be of a standardized size and configuration.

As used herein, the term “node” refers to a computing device that can be configured to receive and respond to requests to perform computing operations. A node may have one processor or multiple processors. In some embodiments, a node includes one or more servers and/or one or more data processing modules.

As used herein, the term “tank” refers to a container with or without a lid, containing a liquid coolant into which one or more data processing modules may be installed.

As used herein, an “independently operable” device means capable of usefully functioning without regard to an operational status of an adjacent device. As used herein, an “independently operable data processing module” means a data processing module that is capable of usefully functioning to provide data processing services and without regard to an operational status of an adjacent data processing module. Operation of independently operable data processing modules can be influenced (e.g., heated) by one or more adjacent data processing modules, but as used herein, an independently operable data processing module generally functions regardless of whether an adjacent data processing module operates or is operable.

As used herein, the term “liquid coolant” may be any sufficiently nonconductive liquid such that electrical components (e.g., a motherboard, a memory board, and other electrical or electronic components designed for use in air) continue to reliably function while submerged without significant modification. A suitable liquid coolant is a dielectric liquid coolant, including without limitation vegetable oil, mineral oil, transformer oil, or any liquid coolant have similar features (e.g., a non-flammable, non-toxic liquid with dielectric strength better than or nearly as comparable as air).

As used herein, “fluid” means either a liquid or a gas, and “cooling fluid” means a gas or liquid coolant typically used for heat-rejection or cooling purposes. As used herein, a liquid coolant is a subset of the universe of cooling fluids, but a cooling fluid may be a dielectric or non-dielectric liquid or gas, such as, for example, a conventional air conditioning refrigerant.

The flowchart and block diagrams in the drawings illustrate the architecture, functionality, and operation of possible implementations of systems, methods and program products, according to various embodiments of the present invention.

While this specification contains many specifics, these should not be construed as limitations on the scope of the invention or of what can be claimed, but rather as descriptions of features specific to particular implementations of the invention. Certain features that are described in this specification in the context of separate implementations can also be implemented in combination in a single implementation. Conversely, various features that are described in the context of a single implementation can also be implemented in multiple implementations separately or in any suitable sub combination. Moreover, although features can be described above as acting in certain combinations and even initially claimed as such, one or more features from a claimed combination can in some cases be excised from the combination, and the claimed combination can be directed to a sub combination or variation of a sub combination.

Similarly, the separation of various system components in the implementations described above should not be understood as requiring such separation in all implementations, and it should be understood that the described program components and systems can generally be integrated together in a single software product or packaged into multiple software products.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, parts and processes may be reversed, and certain features of the invention may be utilized independently, all as would be apparent to one skilled in the art after having the benefit of this description of the invention. Methods may be implemented manually, in software, in hardware, or a combination thereof. The order of any method may be changed, and various elements may be added, reordered, combined, omitted, modified, etc. Changes may be made in the elements described herein without departing from the spirit and scope of the invention as described in the following claims.

1. A computing module, comprising:
one or more racks, wherein at least one of the racks comprises:
one or more servers; and
one or more tanks configured to hold liquid coolant for one or more servers; and
a liquid coolant held in at least one of the tanks and configured to remove heat from at least one of the one or more servers;
one or more cooling components, wherein at least one of the cooling components is configured to move a liquid to remove heat from at least one of the servers in at least one of the racks; and
one or more power distribution components, wherein at least one of the power distribution components is configured to supply power to at least one of the one or more servers in at least one of the racks,
wherein the one or more racks, one or more cooling components, and one or more power distribution components are commonly coupled to one another to be movable as a unit.

2. The computing module of claim 1, further comprising a movable base, wherein the racks, cooling components, and power distribution components are supported on the base.

3. The computing module of claim 1, wherein at least one of the one or more cooling components is configured to couple with one or more external water lines, wherein the cooling components are configured to reject heat into water passing through at least one of the connected external water lines.

4. The computing module of claim 1, wherein at least one of the one or more power distribution components is configured to couple with one or more power sources, wherein the power distribution components are configured to supply power from the one or more power sources to servers in the one or more racks.

5. The computing module of claim 1, wherein the one or more cooling components comprise:
a heat exchanger component; and
a pump component.

6. The computing module of claim 1, wherein at least one of cooling components or power distribution components comprises one or more sub-modules, wherein the one or more sub-modules are configured to be shipped separately from the other portions of the computing module and assembled on-site.

7. The computing module of claim 1, wherein at least one of the cooling components or power distribution components are separately removable.

8. The computing module of claim 1, wherein at least one of the cooling components or power distribution components comprises one or more bays for one or more devices for providing cooling or power for servers in at least one of the racks.

9. The computing module of claim 1, wherein at least one of the cooling components comprises one or more bays for one or more power distribution devices for at least one of the racks.

10. The computing module of claim 1, wherein at least one of the cooling components comprises one or more bays for one or more pumps for moving liquid to cool servers in at least one of the racks.

11. The computing module of claim 1, wherein the base comprises a standard shipping container.

12. The computing module of claim 1, wherein the one or more racks comprise two or more racks mounted on the base, wherein at least one of the cooling component is configured to move a liquid to remove heat from servers is at least two of the racks.

13. The computing module of claim 1, wherein the one or more racks comprise two or more racks mounted on the base, wherein at least one of the cooling component is configured to move a liquid to remove heat from servers is at least two of the racks.

14. The computing module of claim 1, wherein the one or more racks comprise two or more racks mounted on the base, wherein at least one of the cooling component is configured to move a liquid to remove heat from servers is at least two of the racks.

15. The computing module of claim 1, wherein the one or more racks comprise four racks mounted on the base, wherein at least one of the cooling component is configured to move a liquid to remove heat from servers is at least two of the racks.

16. The computing module of claim 1, wherein at least one of the cooling components is configured to move a fluid to remove heat from at least one of the racks.

17. The computing module of claim 1, wherein at least one of the cooling components comprises one or more ports for receiving an external cooling liquid.

18. The computing module of claim 1, wherein at least one of the cooling components comprises a heat exchanger configured to reject heat from liquid coolant in at least one of the racks to another liquid.

19-32. (canceled)

33. A method of computing, comprising:
coupling one or more liquid cooling components and one or more power distribution components to one or more racks;
supplying power from at least one of the power distribution components to at least server in at least one of the racks;
operating at least one of the servers in at least one of the racks to perform computing operations while the at least one server is at least partially submersed in a dielectric liquid coolant; and
moving liquid in at least one of the liquid cooling modules to remove heat from at least one of the servers that is operated in the at least one rack.

34-48. (canceled)

49. A computing module, comprising:
one or more racks, wherein at least one of the racks comprises:
one or more servers;
one or more tanks configured to hold liquid coolant for one or more servers; and
a liquid coolant held in at least one of the tanks and configured to remove heat from at least one of the one or more servers;
one or more cooling components, wherein at least one of the cooling components is configured to move a liquid to remove heat from at least one of the servers in at least one of the racks; and
one or more power distribution components, wherein at least one of the power distribution components is configured to supply power to at least one of the one or more servers in at least one of the racks,
a cooling tower coupled to at least one of the cooling components, wherein the cooling tower is configured to remove heat from at least one circulating liquid carrying heat from at least one of the racks.

50-52. (canceled)
